(19) United States
(12) Patent Application Publication
(10) Pub. No.: US 2025/0391631 A1
(43) Pub. Date: Dec. 25, 2025

(54) LIGHT COLLECTION/INJECTION MIRROR ALIGNMENT

(71) Applicant: ATTOLIGHT AG, Ecublens (CH)

(72) Inventors: Christian Monachon, Montreux (CH); Nicolas Tappy, Fribourg (CH); Nicholas Paul Morgan, Renens (CH)

(21) Appl. No.: 19/244,990

(22) Filed: Jun. 20, 2025

Related U.S. Application Data
(60) Provisional application No. 63/662,955, filed on Jun. 21, 2024.

(51) Int. Cl. H01J 37/22; H01J 37/02; H01J 37/21

(52) U.S. Cl. CPC H01J 37/228; H01J 37/023; H01J 37/21; H01J 37/222

(57) ABSTRACT

An apparatus and method are described for light injection to a parabolic mirror within an electron microscope, light collection from the parabolic mirror, and light collection/injection mirror alignment. The apparatus uses a first mirror, a second mirror, a light source, and a camera, coupled to the electron microscope. Iterations are performed of adjusting inclination of the first mirror to center an image and adjusting inclination or position of the second mirror to center an image. In one version, camera focus is set to mirror image plane focus and set to infinity focus, while centering of the image is observed during mirror adjustment. In one version, camera lens aperture is set to open and set to closed, while centering of the image and brightness of the image are observed during mirror adjustment.

### CROSS-REFERENCE TO RELATED APPLICATIONS

This application claims benefit of priority from U.S. Provisional Application No. 63/662,955 titled LIGHT COLLECTION/INJECTION MIRROR ALIGNMENT and filed Jun. 21, 2024, which is hereby incorporated by reference.

### TECHNICAL FIELD

The technical field of the present disclosure relates to light injection and light collection in electron microscopes, more specifically to light collection/injection mirror alignment for use with an electron microscope, and more generally to optics technology in the context of electron microscope technology.

### BACKGROUND

Electron microscopes are in widespread use in many fields of science, engineering and technology, for example in research, development, and analysis of physical structure, composition, chemical, biological, etc. samples. Sensing and/or imaging from electrons may be combined with sensing and/or imaging from photons (see FIG. 1) in some electron microscopes with specialized equipment. Precision in measurements and observations by the skilled electron microscope operator benefits from precision and tight tolerances in manufacturing, assembly, tuning, and operation of the electron microscope and specialized equipment for combining electron-based sensing or imaging and photon-based sensing or imaging.

In cathodoluminescence spectroscopy, the prevailing technique for light collection is to use a reflective mirror that is either inserted inside the pole piece of an electron microscope, or between said pole piece and the sample that needs to be investigated. The same type of design can be used to inject light into the electron microscope in order to investigate the sample using photons as well as electrons. The preferred form of light for injection is that of a laser, but this can be extended to various light sources. For example, collimated white light, multispectral light, monochromatic or polychromatic light may be used.

A reliable apparatus and method to do precise light collection/injection mirror alignment is currently missing. The main challenge lies in the fact that it is hard to make the electron beam of the electron microscope and the photon beam of the laser (or other light source) match perfectly spatially. More specifically, it is hard to make the electron beam and photon beam match spatially while keeping the photon beam tightly focused with minimum aberrations.

### SUMMARY

Light collection and light injection may be performed with an apparatus coupled to an electron microscope, to expand capabilities of the electron microscope for various observations and measurements. Light collection and light injection are improved with precise light collection/injection mirror alignment, as described herein with respect to various embodiments. In some embodiments, a method may be performed manually with an apparatus. In some embodiments, a method may be performed with an apparatus having some automation. In some embodiments, a method may be performed fully by the apparatus having full automation. That is, across various embodiments of apparatus, there is a range of method embodiments and practice from fully or majority manual to majority or fully automatic or automated.

One embodiment is a method that includes changing focus setting of a variable focus camera lens of a camera, in an apparatus for light injection to a parabolic mirror within an electron microscope and light collection from the parabolic mirror. The apparatus has a light source, the camera with the camera lens, and a light collection/injection mirror arrangement. The light collection/injection mirror arrangement has a first mirror closer to the parabolic mirror and a second mirror less close to the parabolic mirror. The method includes adjusting inclination of the first mirror and inclination or position of the second mirror in the apparatus, to converge on light collection/injection mirror alignment. Adjusting inclination of the first mirror and inclination or position of the second mirror includes iteration of A and B, as follows.
A includes, with the variable focus of the camera lens set to a mirror image plane focus, adjusting the inclination or the position of the second mirror to move an image of the parabolic mirror on a camera image to an image of the parabolic mirror centered position in the camera image.
B includes, with the variable focus of the camera lens set to an infinity focus, adjusting inclination of the first mirror to move a more focused spot on the camera image to a focused spot centered position in the camera image.

Another embodiment is a method that includes changing aperture setting of a variable aperture fixed or infinity focus camera lens of a camera, in an apparatus for light injection to a parabolic mirror within an electron microscope and light collection from the parabolic mirror. The apparatus has a light source, the camera with the camera lens, and a light collection/injection mirror arrangement. The light collection/injection mirror arrangement has a first mirror closer to the parabolic mirror and a second mirror less close to the parabolic mirror. The method includes adjusting inclination of the first mirror and adjusting inclination or position of the second mirror in the apparatus, to converge on light collection/injection mirror alignment. Adjusting inclination of the first mirror and inclination or position of the second mirror includes iteration of A and B, as follows.
A includes, with the variable aperture of the camera lens set to more open, adjusting the inclination of the first mirror to move a bright spot on a camera image to a bright spot centered position in the camera image.
B includes, with the variable aperture of the camera lens set to more closed to dim the bright spot in the camera image, adjusting the inclination or the position of the second mirror to restore brightness of the spot in the camera image.

Another embodiment is an apparatus that has a mounting and a controller. The mounting is for a light source, for a camera having a camera lens, and for coupling to an electron microscope that has a parabolic mirror. The mounting has a light collection/injection mirror arrangement, which has a first mirror that is to be closer to the parabolic mirror, and a second mirror that is to be less close to the parabolic mirror, in coupling to the electron microscope. The controller is arranged to perform a method. The method includes changing a setting of the camera lens and adjusting inclination of the first mirror and inclination or position of the second mirror in the light collection/injection mirror arrangement, to converge on light collection/injection mirror alignment. Adjusting inclination of the first mirror and inclination or position of the second mirror, to converge on alignment, includes iteration of A and B as follows.
A includes, with variable focus of the camera lens set to a mirror image plane focus, adjusting the inclination or the position of the second mirror to move an image of the parabolic mirror on a camera image to an image of the parabolic mirror centered position in the camera image.
B includes, with the variable focus of the camera lens set to an infinity focus, adjusting inclination of the first mirror to move a more focused spot on the camera image to a focused spot centered position in the camera image.
   Alternatively, the iteration of A and B is as follows.
A includes, with variable aperture of the camera lens set to more open, adjusting inclination of the first mirror to move a bright spot on a camera image to a bright spot centered position in the camera image.
B includes, with the variable aperture of the camera lens set to more closed to dim the bright spot in the camera image, adjusting the inclination or the position of the second mirror to restore brightness of the spot in the camera image.

Other aspects and advantages of the embodiments will become apparent from the following detailed description taken in conjunction with the accompanying drawings which illustrate, by way of example, the principles of the described embodiments.

### BRIEF DESCRIPTION OF THE DRAWINGS

The described embodiments and the advantages thereof may best be understood by reference to the following description taken in conjunction with the accompanying drawings. These drawings in no way limit any changes in form and detail that may be made to the described embodiments by one skilled in the art without departing from the spirit and scope of the described embodiments.

FIG. 1 is a depiction of the prior art, wherein a primary electron beam strikes a target, producing backscattered electrons, secondary electrons, x-rays, and cathodoluminescence, as may occur in an electron microscope.

FIG. 2 depicts an embodiment of a mirror positioning system that can be mounted to an electron microscope and has the capability of performing an alignment procedure in accordance with the present disclosure.

FIG. 3 depicts cathodoluminescence with a parabolic mirror, as can be seen in an electron microscope, and which will benefit from an alignment procedure in accordance with the present disclosure.

FIG. 4 depicts an apparatus setup using a camera with variable focus, which may be used in an alignment procedure, in embodiments described herein.

FIG. 5 depicts an apparatus with specific design and arrangement of components for light injection (free space) using two mirrors, which may be coupled to an electron microscope and may be used in an alignment procedure, in embodiments described herein.

FIG. 6 depicts camera images as seen or processed in practicing an alignment procedure for the two mirrors of the FIG. 5 apparatus embodiment, and variations thereof.

FIG. 7 depicts an apparatus with specific design and arrangement of components for light injection (free space) using one mirror and a horizontal-vertical shift plate, which may be coupled to an electron microscope and may be used in an alignment procedure, in embodiments described herein.

FIG. 8 depicts an apparatus with specific design and arrangement of components for light injection for a sample which does not luminesce, which may be coupled to an electron microscope and may be used in an alignment procedure, in embodiments described herein.

FIG. 9 depicts camera images as seen or processed in practicing an alignment procedure for two mirrors of various apparatus embodiments described herein, and variations thereof, using a fixed focus camera with an adjustable aperture.

FIG. 10 depicts camera images as seen or processed in alignment of the parabolic mirror with the sample, which may precede alignment of the two mirrors, in embodiments.

FIG. 11 depicts a collection rod that can be used in switching from light collection mode to light injection mode, in embodiments.

FIG. 12 depicts electron microscope equipment and operating modes that benefit from an alignment procedure using embodiments described herein, for light injection+panchromatic imaging, and hyperspectral imaging with SEM-CL (scanning electron microscope-cathodoluminescence).

FIG. 13A depicts a flow diagram for a technological method of light collection/injection mirror alignment, which produces a practical and useful result of alignment of mirrors in an apparatus coupled to an electron microscope.

FIG. 13B depicts a flow diagram for a further technological method of light collection/injection mirror alignment, which produces a practical and useful result of alignment of mirrors in an apparatus coupled to an electron microscope.

### DETAILED DESCRIPTION

Electron microscopes may be fitted, or retrofitted, with specialized optical equipment, to perform light injection to the electron microscope and to the sample and/or to perform light collection from the electron microscope and the sample. For example, a sample may reflect light, from light injection. A sample may produce light, from light injection, via photoluminescence. A sample may produce light, from electron interaction with the sample, via cathodoluminescence (CL). This is actually practically always the case, because as a minimum the sample will emit transition radiations due to the interaction of the electron beam and the matter of the sample. Light collection, with the proper optical equipment, may be used for spectral analysis, imaging, etc., with appropriate sensors. Best accuracy of measurements, observations, correlation of electron-based imaging and photon-based imaging, correlation of electron-based sensing and photon-based sensing, combinations of sensing and imaging, etc., are obtained with precision alignment of the specialized optical equipment. Precision alignment of the electron and magnet or magnetics-based components (e.g., magnetic lenses operating using electromagnetic coils) of the electron microscope is assumed and is outside of the scope of the present disclosure.

Described herein are various embodiments for light collection/injection mirror alignment, which have the practical application of technological apparatus operation resulting in improved alignment of light collection/injection mirrors as used in light collection and/or light injection with an electron microscope. Embodiments include technological processes, apparatus, manual operation of apparatus, mechanized operation of apparatus, automated operation of apparatus, variations, and envisioning of further embodiments. One application for the embodiments is in cathodoluminescence spectroscopy. Other applications for the embodiments include light collection from sample reflection of light injection, and light collection from sample photoluminescence following light injection. Applications include light sensing and imaging. Applications include light sensing or imaging, with electron beam on, or electron beam off. Not all applications involve sensing of light. For example, injected light can be used to heat a sample or provoke electronic excitations. In such cases, it may not be necessary to sense light coming from the sample, but there is a need to ensure the injected light is well-aligned.

The embodiments of the invention provide a reliable apparatus and method to do precise light collection/injection mirror alignment, helping to overcome the main challenge that it is hard to make the electron beam of the electron microscope and the photon beam of the laser (or other light source) match perfectly spatially. This is challenging to do while keeping the photon beam tightly focused with minimum aberrations, which present embodiments accomplish.

One concept and mechanism for present embodiments is to use the combination of either two mirrors adjustable in inclination and a camera or one mirror, one horizontal-vertical translation stage and a camera, in order to achieve a reliable and reproducible optical alignment for optimum injection and collection of light in an electron microscope. One part of this design is that, for various embodiments, the camera is equipped with either a lens that enables to image (e.g., adjust to focus on) both objects that are close (e.g., at a distance down to 20 cm) and at infinity. Or, for various embodiments, the camera is equipped with a variable aperture that can close to restrict the angle of light entering the lens. For some embodiments, the camera has a fixed focus and a variable aperture or can be set at a specified focus while aperture is varied. The proper denomination for a lens that can image objects at variable distance is «adjustable focus (fixed focal length) camera lens». For some embodiments, the most important camera feature is to be able to vary the camera's focus to image both the light collection system's pupil (herein referred to as “mirror imaging”, i.e., setting focus at the image plane of the mirror) as well as to image infinity (i.e., setting focus at infinity). The lens might have other features encountered in camera lenses such as telecentricity, zoom, variable speed (aperture), etc., although they are not required.

At essence in some embodiments this design is the use of the optical elements to align a collected CL emitted beam straight into the camera by iteratively aligning the signal in the center of the camera sensor, going back and forth between infinity focus and close focus. More specifically, the camera focus is changed back and forth between focus at infinity and focus at “mirror imaging.” At each focus setting, one of the mirrors is adjusted, as further described below, and this process is iterated, with optical alignment homing in further at each iteration. As a variation, for some embodiments the camera aperture is progressively closed while iterating adjustments to the mirrors, instead of changing the focus setting.

The concept can also be extended to samples which exhibit luminescence other than CL, such as photoluminescence (PL). The concept can be extended to samples which do not exhibit luminescence by using instead a sample that diffusively reflects light that is injected with the same parabolic mirror that is used for light collection within the electron microscope. Cathodoluminescence and embodiments related thereto are further explained below. Extensions, variations, and further embodiments are readily understood.

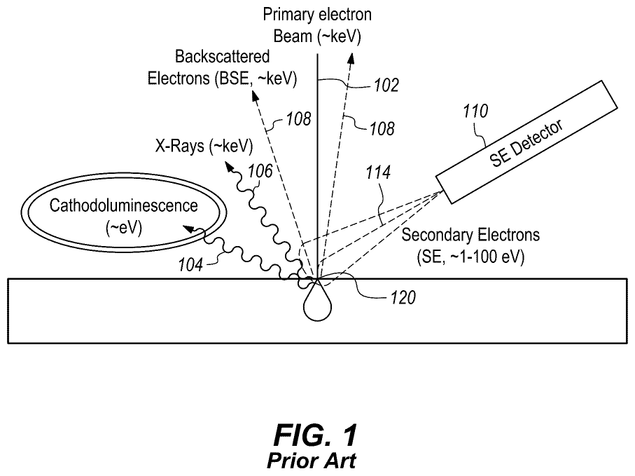

FIG. 1 is a depiction of a prior art configuration wherein a primary electron beam 102 strikes a target 120, producing backscattered electrons 108, secondary electrons 114, x-rays 106, and cathodoluminescence 104, as may occur in an electron microscope. In the electron microscope, a secondary electron (SE) detector 110 senses the secondary electrons 114, which may occur in a range of 1-100 electron volts (eV). Backscattered electrons (BSE) may also be sensed and may occur in the kilo electron volt (keV) range. Particularly, the scanning electron microscope performs imaging based on sensed electrons. X-rays may be sensed for analysis or imaging and may occur in the keV range. Of interest with respect to the present embodiments, cathodoluminescence may be sensed or imaged, and may occur in the eV range (i.e., light or photons in the eV range, produced by the sample). Of further interest with respect to the present embodiments, light collection has historically been done using parabolic mirrors, and that it lends itself well to injection with lasers, because an off axis parabolic mirror takes a parallel beam to focus it in a tight spot, or conversely takes emission from a tight spot and outputs it as a parallel beam.

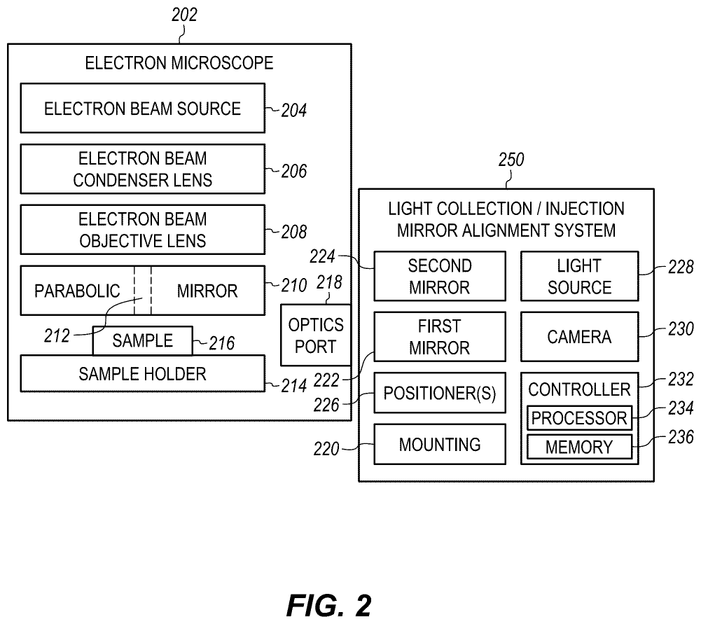

FIG. 2 depicts an embodiment of a mirror positioning system that can be mounted to an electron microscope 202 and has the capability of performing an alignment procedure in accordance with the present disclosure. The electron microscope 202 is illustrated as having an electron beam source 204, electron beam condenser lens 206, electron beam objective lens 208, parabolic mirror 210 with an aperture 212 for passage of electron beam, and a sample holder 214. A sample 216 is presented by the sample holder 214, for the electron beam to strike. Photons, or light, from the sample 216 (e.g., cathodoluminescence, photoluminescence, illumination reflection) is collected by the parabolic mirror 210 and passes out of the electron microscope 202 through the optics port 218, for light collection by the light collection/injection mirror alignment system 250, which also functions for both light injection and light collection. That is, this and other embodiments could have functional naming as a light collection and light injection system, a light collection/injection mirror alignment system, a mirror positioning system, etc., as these are all functions of such embodiments.

Here, the light collection/injection mirror alignment system 250 is coupled to the electron microscope 202 to have capability of light injection through the optics port 218 and capability of light collection through the optics port 218. The light collection/injection mirror alignment system 250 has the capability and functionality of aligning the light collection/injection mirror, in various embodiments.

The light collection/injection mirror alignment system 250 has a first mirror 222, a second mirror 224, positioner(s) 226, mounting 220, a light source 228 (which may be removable in various embodiments), a camera 230 (which may be removable in various embodiments), and in some embodiments (e.g. partial to full automation mirror alignment) has a controller 232 with processor 234 and memory 236. FIG. 2 is in block diagram form, and specific physical arrangement of components is not drawn to scale but it is understood in light of further embodiments depicted and described herein. Generally, the first mirror 222 is closer to the parabolic mirror 210 in the optics path or light path than the second mirror 224, in the light collection/injection mirror arrangement. The first mirror 222 may be purely reflective, the second mirror may be purely reflective, or combination reflective and transmissive (e.g., dichroic, beam splitter, two-way mirror) for various embodiments.

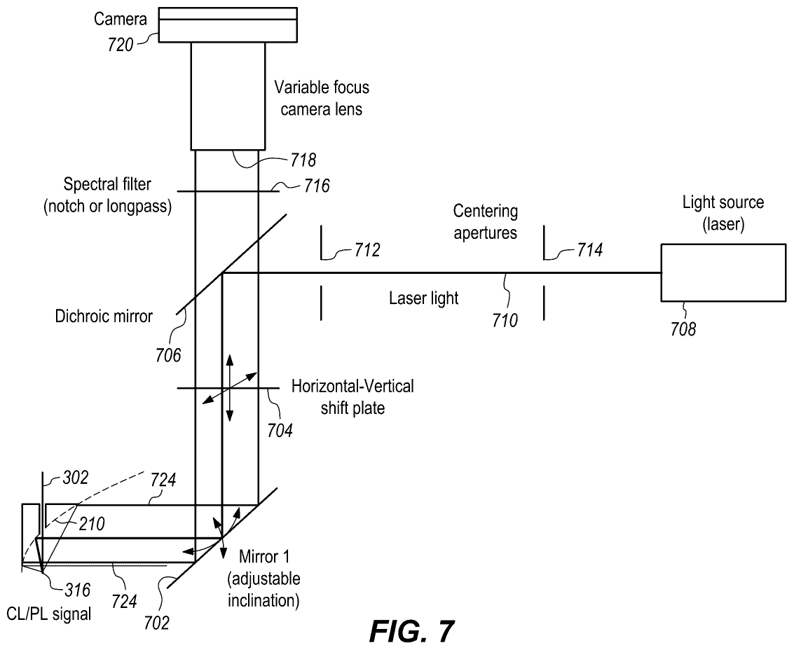

The mounting 220 holds the various components relative to one another and relative to attachment or proximate stable positioning to the electron microscope 202, particularly relative to the optics port 218. Positioner(s) 226 may be manually operable, for example precision screw or caliper adjustment positioners, or electric motorized positioners with manual switch control. For alternative embodiments, positioners may be operable by a controller 232—for example, electric motorized positioners with computer control (e.g., stepper motors or servomotors). The positioner(s) 226 adjust tilt of the first mirror 222 and the second mirror 224, in various embodiments, and this may be done by directly tilting one or both mirrors independently of one another, or tilting part of the mounting such as a platform or plate (see FIG. 7), or other mechanical arrangement readily devised in keeping with the teachings herein. Specific fixtures for the mounting 220 may be available from commercial sources or developed and fabricated or assembled specifically for embodiments.

Examples of light source 228 and camera 238 are described herein, and further examples or embodiments are readily understood. Various arrangements of first mirror 222 and second mirror 224 are described herein, along with other optical equipment particular to specific embodiments, with further embodiments understood.

For the controller 232, some embodiments omit the controller 232 altogether and employ a skilled operator to manually perform an alignment process using the positioner(s) 226 to adjust tilt of the first mirror 222 and the second mirror 224. Some embodiments use the controller 232 to operate the positioner(s) 226 (e.g., computer-controlled motorized positioners), with operator input (e.g. user interface in communication with or part of the controller 232), so that the alignment process is partly computerized and partly manual.

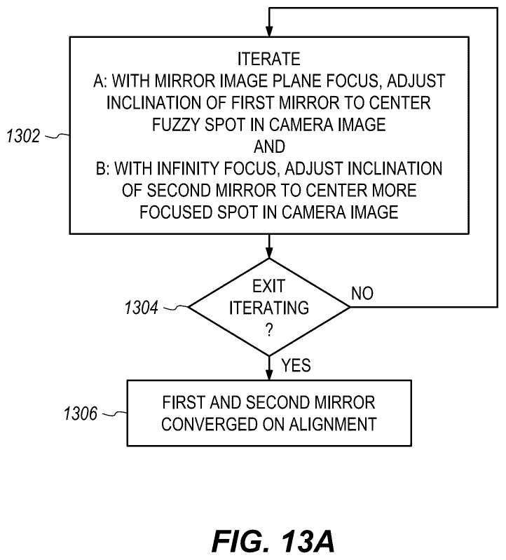

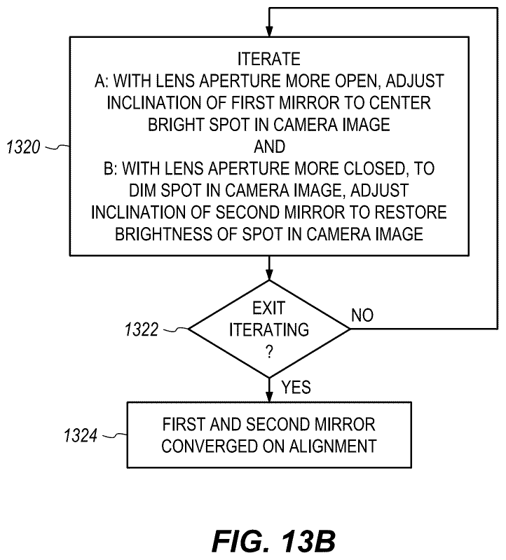

Some embodiments use a fully automated controller 232 to operate the positioner(s) 226 to perform an alignment process for adjusting tilt of the first mirror 222 and the second mirror 224. For example, the alignment process is automated through the controller 232 performing image processing from the camera (e.g., through camera data interface) to detect optical alignment of the mirrors, and a programmed sequence to operate camera settings (e.g., through camera control interface) and adjust tilt of the mirrors, with a closed loop feedback algorithm based on image processing and appropriate parameters for adjustment range and iteration loop exit (see also FIG. 13A and FIG. 13B). Alternatively, there could be a fixed or programmable number of iterations of mirror adjustment, for example between three and ten iterations or between three and thirty iterations, in some embodiments. Regardless of how the number of iterations of mirror adjustment is determined or exit from iterating is determined, the first mirror and the second mirror converge on alignment for light collection or light injection with the electron microscope, for present embodiments.

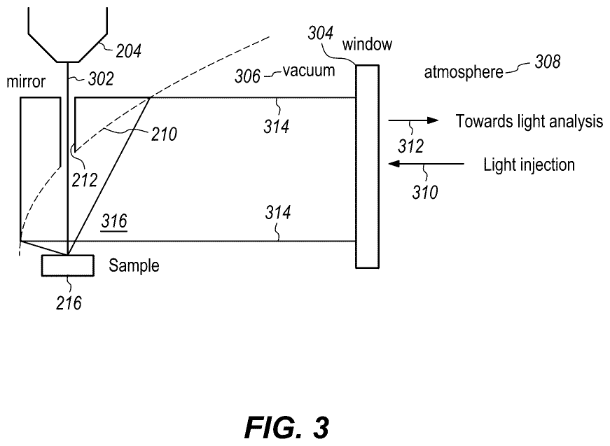

FIG. 3 depicts cathodoluminescence with a parabolic mirror 210, as can be seen in an electron microscope, and which will benefit from an alignment procedure in accordance with the present disclosure. Inside the electron microscope (see also FIG. 2), the electron beam 302 from the electron beam source 204 passes through the aperture 212 of the parabolic mirror 210 and strikes the sample 216, producing cathodoluminescence (i.e. photons, light from the sample and electron impact). These photons, this light, i.e., this cathodoluminescence originates at approximately the focal point of the parabolic mirror 210, due to relative sample 216 positioning, and reflects off the parabolic mirror 210 to produce a parallel beam 314 of light for light collection. Thus far, the light beam 314 is in the vacuum 306 inside the electron microscope 202, on the inside of a window 304, which is part of the optics port 218 of the electron microscope 202 (see FIG. 2). Heading in a direction 312 towards light analysis, the parallel beam 314 of light for light collection, from cathodoluminescence, passes through the window 304 into the atmosphere 308, and this is where the parallel beam 314 interacts with the light collection/injection mirror alignment system 250 (see FIG. 2).

In an opposed direction 310, photons or light for light injection can pass from atmosphere 308 through the window 304 into the vacuum 306 in the reverse direction of the parallel beam 314 of light for light collection. The parabolic mirror 210 focuses such a beam for light injection, on the focal point of the parabolic mirror 210, where the light injection beam will illuminate the sample 216. Optically, these light paths are reversible. A light beam from light injection, illuminating the sample 216, will produce a reflected light beam for light collection, along the reverse path. Alignment of the respective optics is thus relevant both for light collection of cathodoluminescence, and light collection for reflection from light injection onto a sample. Similarly, alignment of the respective optics is relevant for light collection of photoluminescence of a sample, for example following light injection onto the sample.

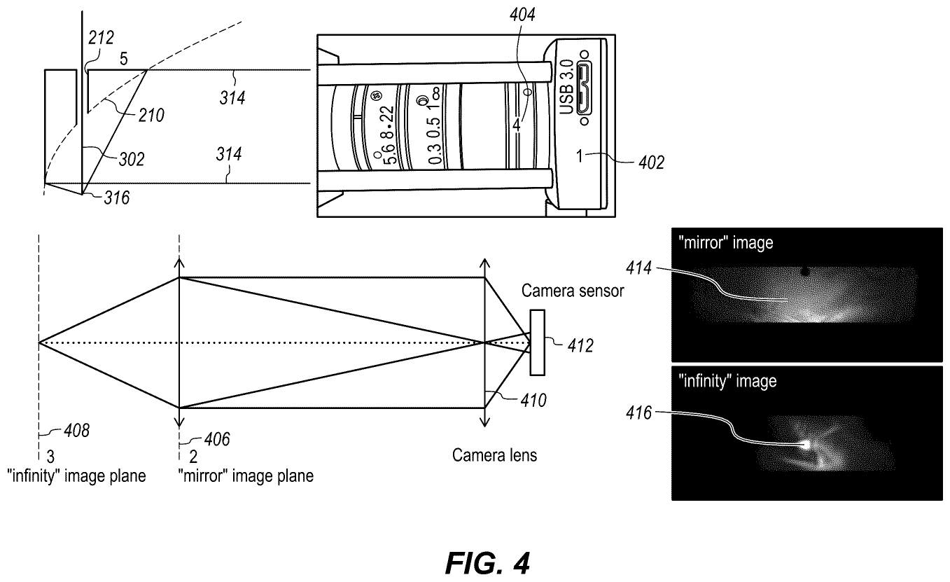

FIG. 4 depicts an apparatus setup using a camera 402 with variable focus, which may be used in an alignment procedure, in embodiments described herein. For the camera 402, there is a camera sensor 412, such as a CCD (charge coupled device) array, positioned relative to a camera lens 410 that has variable focus 404. At one focus setting, the camera 402 produces the “mirror” image 414 from the camera sensor 412, and at another focus setting, the camera 402 six produces the “infinity” image 416 from the camera sensor 412.

The camera 402 (1), needs to be able to image the “mirror” image plane 406 (2) as well as the “infinity” image plane 408 (3), which for a mirror of which output is a parallel beam 314 (5) of light equates to imaging said mirror's focal spot.

This imaging change is done by adjusting the camera lens focus 404 (4). In various embodiments, this action could be performed manually, e.g., by a trained operator, or by a controller 232 (see FIG. 2) coupled to the camera 402, which in turn could be operated with manual input or operating under full automation. Related operation for further embodiments, with aperture adjustment for the camera and camera lens are readily understood.

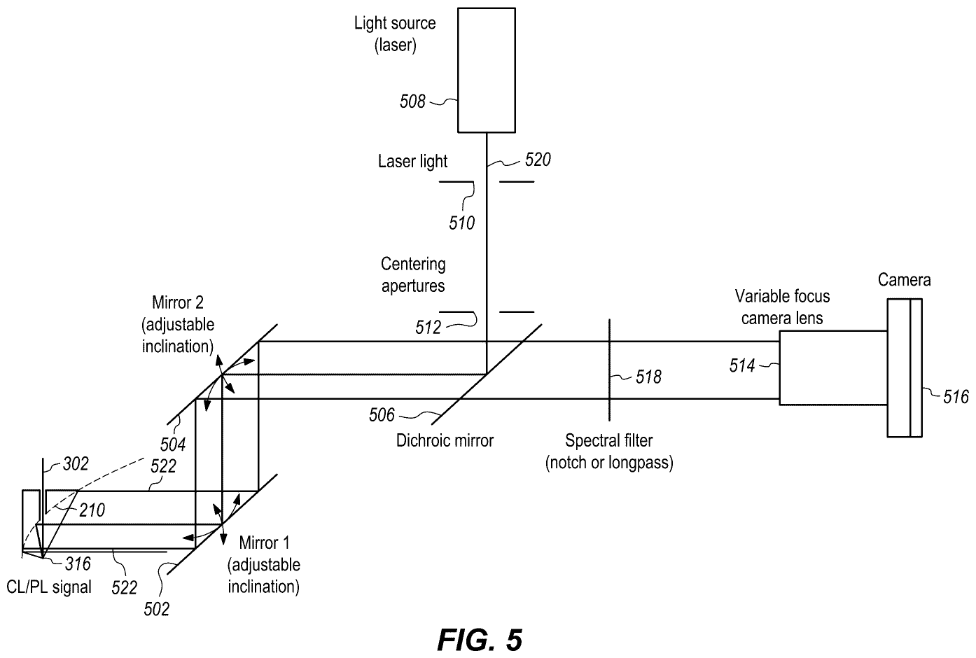

FIG. 5 depicts an apparatus with specific design and arrangement of components for light injection (free space) using two mirrors 502, 504, which may be coupled to an electron microscope and may be used in an alignment procedure, in embodiments described herein. Light injection is from a light source 508, in this example a laser, positioned so that laser light 520 passes through centering apertures 510, 512 (for example apertures through plates) and reflects off a dichroic mirror 506 which is oriented a 45° angle relative to the vertically oriented laser light 520 from the light source 508. The two mirrors are a first mirror 502, Mirror 1, which has adjustable inclination, and a second mirror 504, Mirror 2, which also has adjustable inclination. The two mirrors are also oriented at a 45° angle and are positioned so that the laser light 520 reflected off the dichroic mirror 506 then reflects off the second mirror 504 and reflects off the first mirror 502, aimed towards the parabolic mirror 210 that is inside the electron microscope. Upon focus at the focal point 316 of the parabolic mirror 210, the laser light 520 reflects off the sample, reflects off the parabolic mirror 210 and produces a parallel beam 522 called the CL/PL signal. Upon interaction with the sample at the focal point 316 of the parabolic mirror 210, additional light may be generated by PL, which is also collected by the parabolic mirror 210 and forms part of the parallel beam 522. The parallel beam 522 is a stand-in for the parallel beam that would be produced from CL or PL and is used for the alignment procedure. The parallel beam 522 reflects off the first mirror 502, reflects off the second mirror 504, and passes through the dichroic mirror 506 and through a spectral filter 518 (which may be a notch or long pass filter). The filtered parallel beam 522, i.e., filtered CL/PL signal, enters the variable focus camera lens 514 of the camera 516, where the resultant image may be used in practicing the alignment procedure, as described below. Alternatively, an actual CL or PL parallel beam may be used. That is, when an arrangement of a dichroic mirror 506 with a spectral filter 518 is used, as shown in FIG. 5, the apparatus is for an actual CL or PL signal. If the apparatus is used just for reflected laser light, the dichroic mirror 506 should be replaced by a beam splitter and the spectral filter 518 is no longer needed.

For the alignment procedure, in terms of instructions to the trained operator or an automation controller, make sure that the dichroic mirror 506 is reflecting at a perfect 90° in plane by using appropriate optical components, or by going back and forth with the camera 516 between «laser» and «camera» position (e.g., swapping mounting positions of removable camera 516), making sure that the reflected signal in «infinity» image plane is well centered in both cases. Use the opportunity to make sure that both centering apertures are well centered when the camera 516 is in the «laser» position.

Center CL output beam on the camera image in order by adjusting the first mirror 502, Mirror 1 and the second mirror 504, Mirror 2 by going back and forth between «mirror» image plane and «infinity” image plane, making sure that resultant images are aligned on the camera sensor, following the iterative procedure described below.

Make sure that the laser beam is well centered and perpendicular to the signal line going into the dichroic mirror 506 by using the centering apertures 510, 512.

If PL is used instead of CL, adjusting the mirrors 502, 504 will result in a change of the alignment of the injected laser light, but the concept still holds. The brightness of the collected light may change with adjustments, but this is yet another feedback mechanism to guide the adjustments.

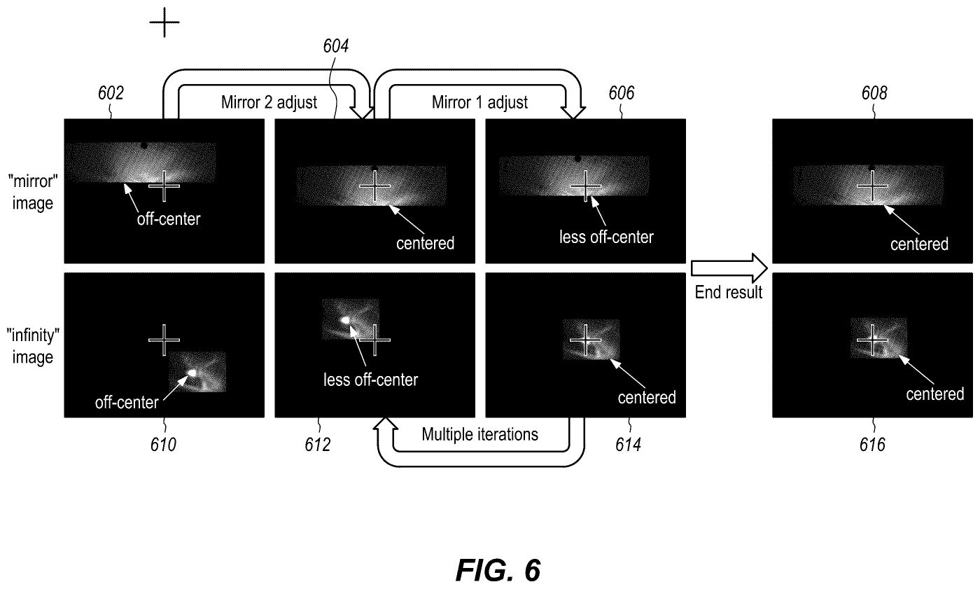

FIG. 6 depicts camera images as seen or processed in practicing an alignment procedure for the two mirrors of the FIG. 5 apparatus embodiment, and variations thereof.

First mirror 502, Mirror 1 and second mirror 504, Mirror 2 inclinations are adjusted in succession to center the mirror image and infinity image on the camera, respectively. When either mirror is adjusted to center the position of an image with a specified camera focus setting, the other image with the other specified camera focus setting inevitably gets displaced from the center. The adjustment process is thus iterative, and convergent on centered images in both camera focus settings. A more detailed walk-through of the alignment procedure is described below.

With the camera focus set for “mirror” image, camera image is observed while adjusting second mirror 504 inclination or tilt, to move the imaged spot from the camera image 602 showing an off-center image of the parabolic mirror, to the camera image 604 showing a centered image of the parabolic mirror. That is, the second mirror 504 is adjusted to center the image of the mirror in the camera field of view. The image seen when the camera focus is set to “mirror image” is actually what the parabolic mirror looks like if one were to view it with the eye. The fuzziness seen in the images may be because the illumination of the mirror by CL/PL is not perfectly uniform on the mirror and we are seeing a 2D projection of a 3D object (the mirror) under this non-uniform illumination. Camera focus is then changed to infinity focus. With the camera focus set for “infinity” image, a focused spot camera image is observed while adjusting first mirror 502 inclination or tilt, so as to move the spot in the camera image 612 from showing a focused, off-center spot, to the camera image 614 showing a focused spot centered. That is, the first mirror 502 is adjusted to center the spot in the camera image. Note that, at “infinity” image, a non-uniform halo might be visible around the bright central spot. If this is a case, the bright spot is taken as the reference point for centering. Camera focus is then changed to mirror image plane focus. With the camera focus set for “mirror” image, after adjusting second mirror 504, the camera image is observed as camera image 606 showing an image of the parabolic mirror less off-center than was initially the case, and the second mirror 504 is again adjusted for inclination or tilt, to move to the camera image 604 showing a centered image of the parabolic mirror. Camera focus is then changed to infinity focus. With the camera focus set for “infinity” image, after adjusting second mirror 504, camera image may be observed as camera image 612 showing a focused spot less off-center than was initially the case, and first mirror 502 is adjusted for inclination or tilt, to move to the camera image 614 showing focused spot centered. After some number of interim iterations, alternating camera focus settings and tilt adjust for a corresponding mirror with each camera focus setting and centering the spot or image of the parabolic mirror, the result is observed in camera focus set for “mirror” image and camera image 608 centered, and camera focus set for “infinity” image and camera image 616 showing a focused spot centered.

The alignment procedure may be started with either camera focus setting and moving the respective mirror, followed by the other camera focus setting, and moving the other mirror, and iterating. The number of iterations to achieve satisfactory results in mirror alignment may be between 3 and 10, for example, or between 3 and 30, for example. For automated operation, for example by a controller, this could be programmed as a specified number of iterations, or a variable number of the iterations to achieve a particular programmed tolerance or specified range of a parameter, in various embodiments.

FIG. 7 depicts an apparatus with specific design and arrangement of components for light injection (free space) using one mirror and a horizontal-vertical shift plate, which may be coupled to an electron microscope and may be used in an alignment procedure, in embodiments described herein. The shift plate 704 (or other positioner fixture in further embodiments) mounts in fixed relationship to one another, the dichroic mirror 706, spectral filter 716 (which may be notch or longpass), camera 720 with variable focus camera lens 718, plates or other fixtures with centering apertures 712, 714 and light source 708 (e.g., laser), and moves all of these components together (but not the first mirror 702) when the shift plate is used to adjust position of the dichroic mirror 706 relative to the first mirror 702. Thus, the dichroic mirror 706 is performing double duty in this embodiment, as the second mirror and also as a light splitter or combination light reflector and pass through device. Light injection from the light source 708 passes through centering apertures 712, 714 and reflects off the dichroic mirror 706, which is oriented at a 45° angle relative to the horizontally oriented laser light 710 from the light source 708. Laser light 710 then reflects off the first mirror 702, Mirror 1, which has adjustable inclination independent of the shift plate and the dichroic mirror 706, and is aimed towards the parabolic mirror 210 that is inside electron microscope. Upon focus at the focal point 316 of the parabolic mirror 210, the laser light 710 for light injection reflects off the sample, reflects off the parabolic mirror 210 and produces a parallel beam 724 called the CL/PL signal (see also FIG. 5 and related description). The parallel beam 724 CL/PL signal reflects off the first mirror 702, passes through the dichroic mirror 706 and through the spectral filter 716. The filtered parallel beam 724, i.e., filtered CL/PL signal, enters the variable focus camera lens 718 of the camera 720, where the resultant image may be used in practicing the alignment procedure, as described below. Note that, when using a dichroic, actual CL or PL is observed or captured in the camera image. If instead the dichroic is replaced with a beam splitter, then the reflected laser light is observed or captured, in a further embodiment.

For the alignment procedure, in terms of instructions to the trained operator or an automation controller, make sure that the dichroic mirror 706 is reflecting at a perfect 90° in plane by using appropriate optical components, or by going back and forth with the camera 720 between «laser» and «camera» position, making sure that the reflected signal in the «infinity» image plane is well centered in both cases. Use the opportunity to make sure that both centering apertures are well centered when the camera is in the «laser» position.

Center «mirror» image on the camera by adjusting the horizontal-vertical shift plate to which the dichroic mirror 706 (and other optical components excluding the first mirror 702) is mounted.

Center «infinity» image on the camera by adjusting tilt (i.e., inclination) of first mirror 702, Mirror 1. Iterate, as before, between adjusting the horizontal-vertical shift plate to center the “mirror” image and adjusting the inclination of the first mirror 702, Mirror 1, to bring the “infinity” image to the center until convergence is achieved and both “mirror” image and “infinity” image are centered.

Make sure that the laser beam is well centered and perpendicular to the signal line going into the dichroic mirror 706 by using the centering apertures 712, 714.

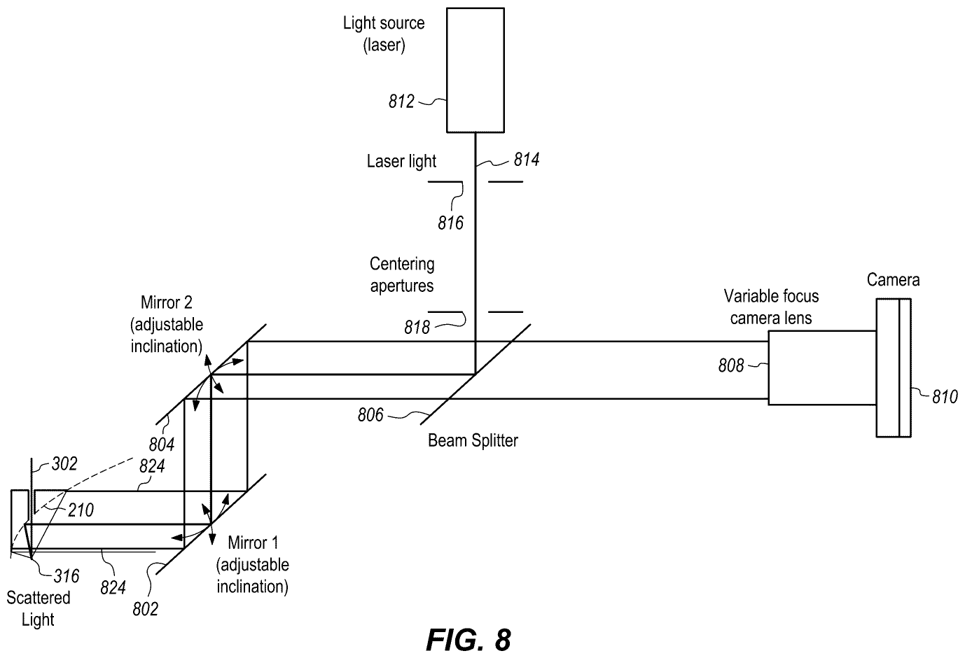

FIG. 8 depicts an apparatus with specific design and arrangement of components for light injection for a sample which does not luminesce, which may be coupled to an electron microscope and may be used in an alignment procedure, in embodiments described herein. The previously described method relies on use of a sample which exhibits either cathodoluminescence (CL) or photoluminescence (PL), which limits the useful applications. A similar procedure can be followed using a sample that reflects or scatters light instead of luminescing. In such a case, the dichroic mirror is simply replaced with a beam splitter 806 and there is no longer need for a spectral filter.

In this example, light injection is from a light source 812, for example a laser, positioned so that laser light 520 passes through centering apertures 816, 818 (e.g., apertures through plates) and reflects off a beam splitter 806 which is oriented at a 45° angle relative to the vertically oriented laser light 814 from the light source 812. Laser light 520 then is reflected off the second mirror 804, Mirror 2 with adjustable inclination, and reflected off the first mirror 802, Mirror 1 with adjustable inclination, aimed at the parabolic mirror 210 that is inside electron microscope. Upon focus at the focal 316 of the parabolic mirror 210, the laser light 520 scatters off the sample as scattered light, which is reflected by the parabolic mirror 210, to form parallel light beam 824 of scattered light. Light beam 824 is reflected off the first mirror 802 and reflected off the second mirror 804, and then passes through the beam splitter 806 to enter the variable focus camera lens 808 of the camera 810. Mirror adjustment is similar to that described above, only using reflected or scattered light instead of luminescence.

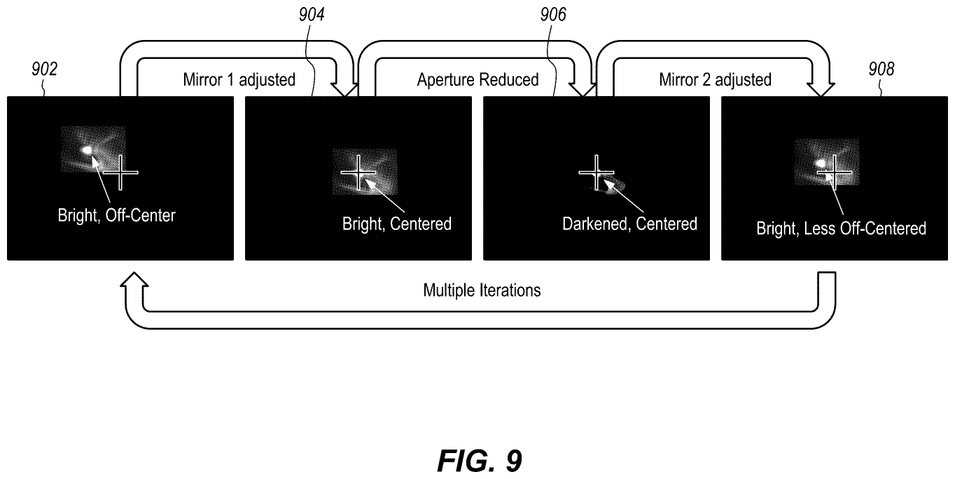

FIG. 9 depicts camera images as seen or processed in practicing an alignment procedure for two mirrors of various apparatus embodiments described herein, and variations thereof, using a fixed focus camera with an adjustable aperture. It is possible to perform the same (or related) iterative alignment process described previously, in using a camera with a single focal length if it is also equipped with an adjustable aperture in front of the lens.

In such a case, the spot is imaged with the camera as the “infinity” image while the aperture is fully open, for example as seen in the camera image 902 with the spot bright and off-center. Tilt adjustment of the first mirror, Mirror 1 is used to bring the spot to the center of the camera field of view, as seen in the camera image 904 with the bright, centered spot. Next, the aperture is closed until the spot starts to dim, as seen in the camera image 906 with the darkened, centered spot. Tilt of the second mirror, Mirror 2 is then adjusted until the brightness of the spot is restored, as seen in the camera image 908 with the bright, less off-center spot. Tilt adjustment of the first mirror, Mirror 1 is used to re-center the spot again. This process is repeated iteratively until the spot brightness and centering cannot be increased further.

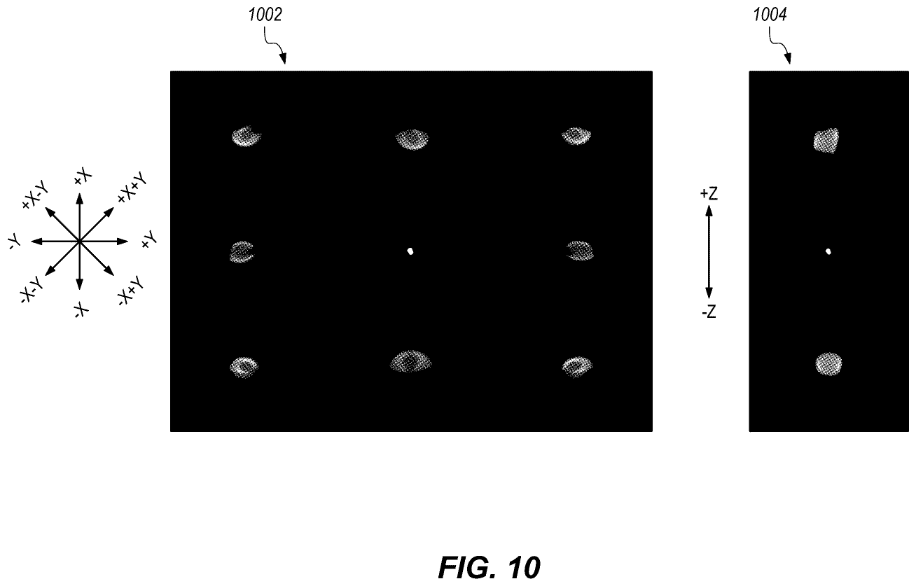

FIG. 10 depicts camera images as seen or processed in alignment of the parabolic mirror with the sample, which may precede alignment of the two mirrors, in embodiments. In order to properly perform the alignment described herein, in some embodiments the parabolic mirror must be positioned properly with respect to the electron beam and the sample surface, such that point of luminescence is in the focal point of the parabolic mirror. It is understood that in some electron microscopes, the parabolic mirror is fixed and not adjustable.

Positioning of the parabolic mirror, when feasible in an electron microscope, is achieved by setting the camera focus to “infinity” and imaging the luminescence spot. The parabolic mirror's position is then adjusted to achieve the smallest, most intense spot on the camera. Images 1002 provide an example of how the imaged “infinity point” changes as the position of the parabolic mirror changes along the X, Y and Z directions.

In the case of using PL, images 1004 provide an example of how the imaged “infinity point” changes as the position of the parabolic mirror changes, however only the Z axis needs adjustment.

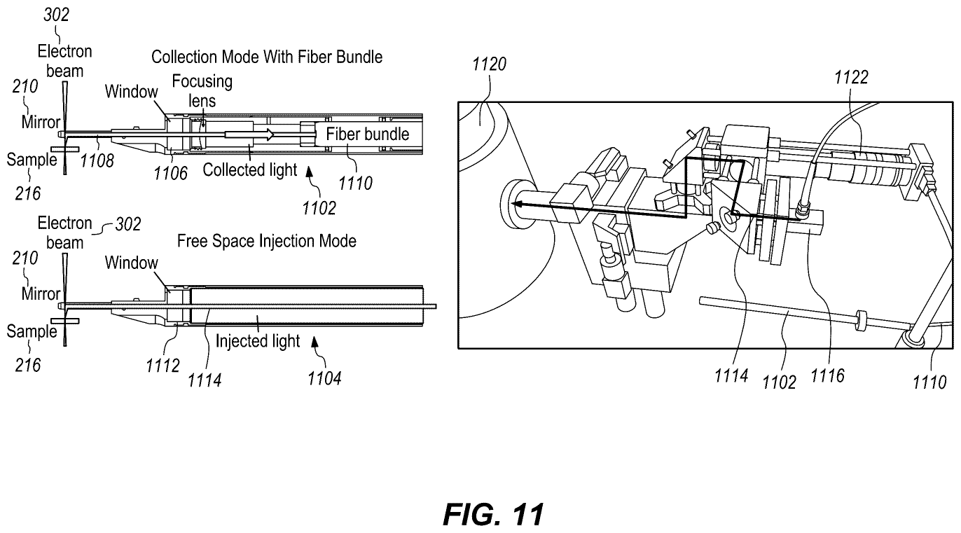

FIG. 11 depicts a collection rod that can be used in switching from light collection mode to light injection mode, in embodiments. To the right, an electron microscope 1120 is shown equipped with a camera 1122 and laser 1116, with injected light 1114 on a reflected light path. Sitting on the mounting table, a collection rod 1102 with fiber bundle 1110 is configured for collection mode with a fiber bundle, as illustrated on the top left in FIG. 11. For collection mode, collected light 1108, for example from a sample 216 and parabolic mirror 210, passes through a window 1106 to the interior of the collection rod 1102, and passes into the fiber bundle 1110. It is understood the other end of the fiber bundle would be attached to sensing or imaging equipment.

Alternatively, to the lower left in FIG. 11, the collection rod 1104 is configured for free space injection mode. For free space injection mode, injected light 1114, for example from a laser, not shown, passes through the interior of the collection rod 1104 and through a window 1112, for free space injection of injected light 1114. Injected light 1114, in this illustration, reflects off the parabolic mirror 210 to the sample 216. An electron beam 302 is also shown striking the sample 216, as previously described.

The collection rod is designed for easy insertion and removal, reliable alignment, easy reconfiguration with fiber bundle or laser, and ruggedness for reliability. Dimensions of various embodiments would be specific to the related equipment and components.

When the apparatus is configured in Free Space Injection Mode or Free Space Collection Mode, the collection rod 1104 must be removed in order for the procedure for alignment to be performed. The collection rod 1104 may be reinstalled so that the apparatus can be operated in Fiber-Coupled Collection Mode. Alignment is preserved with removal and installation of the collection rod 1104, as this is a removable modular component in various embodiments.

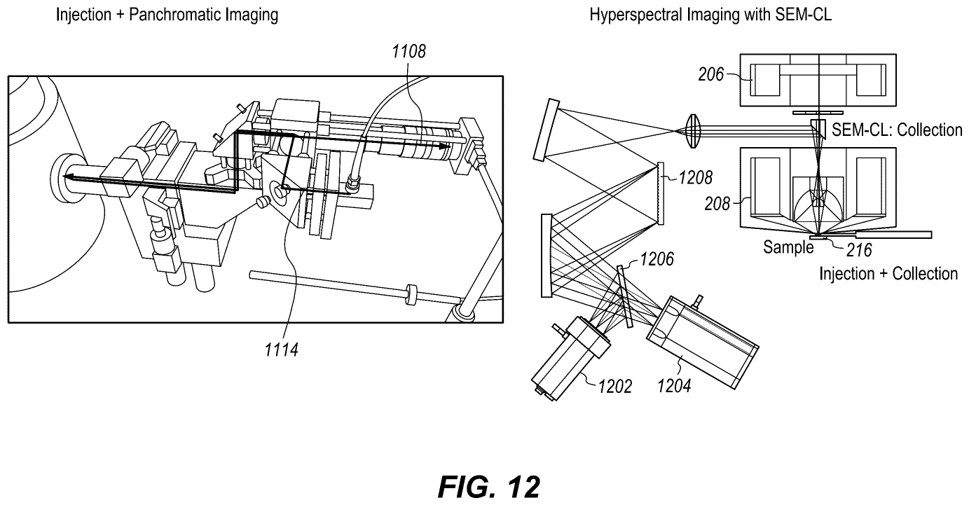

FIG. 12 depicts electron microscope equipment and operating modes that benefit from an alignment procedure using embodiments described herein, for light injection+panchromatic imaging, and hyperspectral imaging with SEM-CL (scanning electron microscope-cathodoluminescence). Injected light 1114 is shown traveling a reflected path and returning collected light 1108 is shown also on a reflected path but separating from the path of the injected light, for separate collection.

On the right, hyperspectral imaging needs an array detector or rotating grating and is slower. Each map pixel contains a full spectrum. This allows for a more refined analysis. The sample 216 is irradiated by an electron beam and produces light (CL). This light is collected by the CL microscope optics and routed to a spectrometer containing a diffraction grating 1208 that creates a wavelength-dependent divergent light beam. This divergent light beam is reflected off a removable mirror 1206 and directed onto an array detector 1202. If removable mirror 1206 is removed, the divergent light beam will be directed onto a different array detector 1204. For example, the two kinds of array detectors 1202, 1204 are used for different wavelength regimes.

Because both of these applications use light injection and light collection, with an electron microscope, the alignment procedures described herein are applicable in embodiments. These apparatuses and usage thereof benefit from such alignment.

FIG. 13A depicts a flow diagram for a technological method of light collection/injection mirror alignment, which produces a practical and useful result of alignment of mirrors in an apparatus coupled to an electron microscope. The method can be practiced manually on apparatus embodiments described herein and can be practiced automatically on or by some apparatus embodiments described herein, particularly with a controller, for example specially programmed.

In the action 1302, A and B are iterated. This could be starting with A, or starting with B, and ending with A or ending with B, iterating A and B or iterating B and A.
A: With the camera lens set for mirror image plane focus, adjust inclination of the second mirror to center the image of the parabolic mirror in the camera image.
B: With the camera lens set for infinity focus, adjust inclination of the first mirror to center a more focused spot in the camera image.

In a determination action 1304, the determination is made whether or not to exit iterating. If the determination is no, the iterating continues with the action 1302. If the determination is yes, the iterating is exited to the action 1306. Exit criteria could include a fixed or programmable number of iterations, in some embodiments, or measurement in comparison to exit criteria (e.g., parameter), as determined by operator, through instrumentation, or as determined by a controller, in various embodiments.

In the action 1306, the first and second mirror are converged on alignment. This may be considered a system status that is achieved, or a tangible, useful result of the iterating, expressed as an action.

FIG. 13B depicts a flow diagram for a technological method of light collection/injection mirror alignment, which produces a practical and useful result of alignment of mirrors in an apparatus coupled to an electron microscope. The method can be practiced manually on apparatus embodiments described herein, and can be practiced automatically on or by some apparatus embodiments described herein, particularly with a controller, for example specially programmed.

In the action 1320, A and B are iterated. This could be starting with A, or starting with B, and ending with A or ending with B, iterating A and B or iterating B and A.
A: With the camera lens aperture set for more open, adjust inclination of the first mirror to center a bright spot in the camera image.
B: With the camera lens aperture set for more closed, to dim the spot in the camera image, adjust inclination of the second mirror to brighten (e.g., maximally) or restore brightness of the spot in the camera image.

In a determination action 1322, the determination is made whether or not to exit iterating. If the determination is no, the iterating continues with the action 1320. If the determination is yes, the iterating is exited to the action 1324. Exit criteria could include a fixed or programmable number of iterations, in some embodiments, or measurement in comparison to exit criteria (e.g., parameter), as determined by operator, through instrumentation, or as determined by a controller, in various embodiments.

In the action 1324, the first and second mirror are converged on alignment. This may be considered a system status that is achieved, or a tangible, useful result of the iterating.

Further embodiments include practicing the alignment procedure, to align first mirror, second mirror and a mounting, then securing the aligned first mirror and second mirror in place in their aligned positions in the mounting. This could be done during manufacturing, for example, in some embodiments with a removable light source and/or removable camera, so that the mounting with aligned first mirror and second mirror could include mountings for these removable components and be sold as a secured aligned fixture. Or the light source and camera could be secured in place in the mounting, so that the secured aligned fixture could be sold including the light source and camera. Further embodiments are readily devised for using the alignment procedure during manufacturing.

The foregoing description, for the purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described to best explain the principles of the embodiments and its practical applications, to thereby enable others to best utilize the embodiments and various modifications as may be suited to the particular use contemplated. Accordingly, the present embodiments are to be considered as illustrative and not restrictive, and the invention is not to be limited to the details given herein but may be modified within the scope and equivalents of the appended claims.

What is claimed is:

1. A method, comprising:
changing focus setting of a variable focus camera lens of a camera, in an apparatus for light injection to a parabolic mirror within an electron microscope and light collection from the parabolic mirror, the apparatus having a light source, the camera with the camera lens, and a light collection/injection mirror arrangement comprising a first mirror closer to the parabolic mirror and a second mirror less close to the parabolic mirror; and
adjusting inclination of the first mirror and inclination or position of the second mirror in the apparatus, to converge on light collection/injection mirror alignment, comprising iteration of:
A: with the variable focus of the camera lens set to a mirror image plane focus, adjusting the inclination or the position of the second mirror to move an image of the parabolic mirror on a camera image to an image of the parabolic mirror centered position in the camera image; and
B: with the variable focus of the camera lens set to an infinity focus, adjusting the inclination of the first mirror to move a more focused spot on the camera image to a focused spot centered position in the camera image.

2. The method of claim 1, wherein the apparatus is to practice the iteration of A and B through a controller coupled to one or more motorized positioners that adjust the inclination of the first mirror and the inclination or the position of the second mirror.

3. The method of claim 1, wherein the iteration of A and B comprises:
starting with A or B, iterating cycles are performed of A followed by B or B followed by A, ending with A or B, so that the first mirror and the second mirror converge on alignment for light collection or light injection with the electron microscope.

4. The method of claim 1, wherein adjusting the inclination of the first mirror and adjusting the inclination or the position of the second mirror are performed manually through positioners coupled to the first mirror and the second mirror.

5. The method of claim 1, wherein adjusting the inclination of the first mirror and adjusting the inclination or the position of the second mirror are performed manually through motorized positioners coupled to the first mirror and the second mirror.

6. The method of claim 1, wherein:
adjusting the inclination of the first mirror is performed through a positioner coupled to the first mirror; and
adjusting the position of the second mirror is performed through a positioner fixture that mounts and moves the second mirror, the camera and the light source, but not the first mirror, in a fixed relationship to one another.

7. The method of claim 1, wherein:
the second mirror comprises a dichroic mirror; and
adjusting the inclination or the position of the second mirror comprises adjusting the position of the dichroic mirror and not adjusting the inclination of the dichroic mirror.

8. A method, comprising:
changing aperture setting of a variable aperture fixed or infinity focus camera lens of a camera, in an apparatus for light injection to a parabolic mirror within an electron microscope and light collection from the parabolic mirror, the apparatus having a light source, the camera with the camera lens, and a light collection/injection mirror arrangement comprising a first mirror closer to the parabolic mirror and a second mirror less close to the parabolic mirror; and
adjusting inclination of the first mirror and inclination or position of the second mirror in the apparatus, to converge on light collection/injection mirror alignment, comprising iteration of:
A: with the variable aperture of the camera lens set to more open, adjusting the inclination of the first mirror to move a bright spot on a camera image to a bright spot centered position in the camera image; and
B: with the variable aperture of the camera lens set to more closed to dim the bright spot in the camera image, adjusting the inclination or the position of the second mirror to restore brightness of the spot in the camera image.

9. The method of claim 8, wherein the apparatus is to practice the iteration of A and B through a controller coupled to one or more motorized positioners that adjust the inclination of the first mirror and the inclination or the position of the second mirror.

10. The method of claim 8, wherein the iteration of A and B comprises:
starting with A or B, iterating cycles are performed of A followed by B or B followed by A, ending with A or B, so that the first mirror and the second mirror converge on alignment for light collection or light injection with the electron microscope.

11. The method of claim 8, wherein adjusting the inclination of the first mirror and adjusting the inclination or the position of the second mirror are performed manually through positioners coupled to the first mirror and the second mirror.

12. The method of claim 8, wherein adjusting the inclination of the first mirror and adjusting the inclination or the position of the second mirror are performed manually through motorized positioners coupled to the first mirror and the second mirror.

13. The method of claim 8, wherein:
adjusting the inclination of the first mirror is performed through a positioner coupled to the first mirror; and
adjusting the position of the second mirror is performed through a positioner fixture that mounts and moves the second mirror, the camera and the light source, but not the first mirror, in a fixed relationship to one another.

14. The method of claim 8, wherein:
the second mirror comprises a dichroic mirror; and
adjusting the inclination or the position of the second mirror comprises adjusting the position of the dichroic mirror and not adjusting the inclination of the dichroic mirror.

15. An apparatus, comprising:
a mounting for a light source, for a camera having a camera lens, and for coupling to an electron microscope having a parabolic mirror;
the mounting having a light collection/injection mirror arrangement comprising a first mirror to be closer to the parabolic mirror and a second mirror to be less close to the parabolic mirror, in coupling to the electron microscope; and
a controller, arranged to perform a method, comprising:
changing a setting of the camera lens; and
adjusting inclination of the first mirror and inclination or position of the second mirror in the light collection/injection mirror arrangement, to converge on light collection/injection mirror alignment, comprising iteration of:
A: with variable focus of the camera lens set to a mirror image plane focus, adjusting the inclination or the position of the second mirror to move an image of the parabolic mirror on a camera image to an image of the parabolic mirror centered position in the camera image; and
B: with the variable focus of the camera lens set to an infinity focus, adjusting inclination of the first mirror to move a more focused spot on the camera image to a focused spot centered position in the camera image; or
A: with variable aperture of the camera lens set to more open, adjusting inclination of the first mirror to move a bright spot on a camera image to a bright spot centered position in the camera image; and
B: with the variable aperture of the camera lens set to more closed to dim the bright spot in the camera image, adjusting the inclination or the position of the second mirror to restore brightness of the spot in the camera image.

16. The apparatus of claim 15, further comprising:
one or more motorized positioners coupled to the controller and arranged to adjust the inclination of the first mirror and the inclination or the position of the second mirror.

17. The apparatus of claim 15, wherein the controller-performed iteration of A and B comprises:
starting with A or B, iterating cycles are performed of A followed by B or B followed by A, ending with A or B, so that the first mirror and the second mirror converge on alignment for light collection or light injection with the electron microscope.

18. The apparatus of claim 15, further comprising:
a positioner coupled to the controller and arranged to adjust the inclination of the first mirror; and
a positioner fixture that mounts and moves the second mirror, the camera and the light source, but not the first mirror, in a fixed relationship to one another, the positioner fixture coupled to the controller and arranged to adjust the inclination of the second mirror.

19. The apparatus of claim 15, wherein:
the second mirror comprises a dichroic mirror; and
adjusting the inclination or the position of the second mirror comprises adjusting the position of the dichroic mirror and not adjusting the inclination of the dichroic mirror.

20. The apparatus of claim 15, wherein the controller-performed iteration of A and B comprises one of:
a programmable number of iterations of A and B
between three and ten iterations, inclusive, of A and B;
between three and thirty iterations, inclusive, of A and B; or
closed loop feedback based on image processing with parameters for adjustment range and iteration loop exit.
